(19) United States
(12) Patent Application Publication
(10) Pub. No.: US 2013/0068013 A1
(43) Pub. Date: Mar. 21, 2013

(54) SENSOR ELEMENT WITH ENGINEERED SILICIDE

(71) Applicants: Scott Edward Beck, Murphy, TX (US); Yong-Fa Wang, Coppell, TX (US)

(72) Inventors: Scott Edward Beck, Murphy, TX (US); Yong-Fa Wang, Coppell, TX (US)

(73) Assignee: HONEYWELL INTERNATIONAL INC., Morristown, NJ (US)

(21) Appl. No.: 13/235,261

(22) Filed: Sep. 16, 2011

(51) Int. Cl. G01F 1/69; G01F 1/68; G01F 1/00; H01L 21/02

(52) U.S. Cl. 73/204.25; 438/48; 73/204.11; 73/272 R; 257/E21.002

(57) ABSTRACT

A sensing element having an integrally formed metal-silicide layer with a silicon layer is described. In some instances, the thickness of the metal-silicide layer can be controlled during fabrication such that the sensing element has a desired resistivity and/or a near linear thermal coefficient of resistance (TCR).

### FIELD

The present disclosure relates generally to sensors, and more particularly, to sensors that include sensor elements such as resistors, heaters and/or other sensor elements.

### BACKGROUND

Sensors are commonly used to sense various parameters in a wide variety of applications including, for example, medical applications, flight control applications, industrial process applications, combustion control applications, weather monitoring applications, as well as many other applications. Sensors often include sensor elements such as resistors, heaters and/or other sensor elements. In many cases, it is desirable for such sensor elements to have well-behaved characteristics, such as resistance and/or temperature coefficient characteristics.

### SUMMARY

The present disclosure relates generally to sensors, and more particularly, to sensors that include sensor elements such as resistors, heaters and/or other sensor elements. In some instances, a sensor element may include a first dielectric layer, a silicon layer on the first dielectric layer, and a metal-silicide layer integrally formed with the silicon layer such that the metal-silicide layer is separated from the first dielectric layer by the silicon layer. In some instances, the silicon layer may include a dopant. The type of metal-silicide, the thickness of the silicon and/or metal layer and the doping concentration of the silicon layer can all be selected to produce a desired resistance and/or temperature coefficient in the resulting sensor element. In some instances, a second dielectric layer may be situated on the metal-silicide layer and may include a dopant. The second dielectric layer may, in some cases, result from some of the silicon atoms and/or dopant diffusing through the metal-silicide layer and becoming oxidized. Regardless of how formed, the second dielectric layer may function as a low stress upper adhesion layer that supports further thin film deposition.

In some cases, the sensor may be a flow sensor that includes a heater element, an upstream sensing element situated upstream of the heater element, and a downstream sensing element situated downstream of the heater element. At least one of the heater element, the upstream sensing element and the downstream sensing element may include a first dielectric layer, a silicon layer on the first dielectric layer, a metal-silicide layer integrally formed with the silicon layer, and in some cases, a second dielectric layer situated on the metal-silicide layer. The silicon layer and/or the second dielectric layer may be doped with a dopant. In some cases, the upstream sensing element and the downstream sensing element may be included in a Wheatstone bridge.

An illustrative method for making a sensor element may include, for example, providing a first dielectric layer, providing a silicon layer on the first dielectric layer, doping the silicon layer with a concentration of a dopant, providing a metal layer on the silicon layer, and heating the silicon layer and the metal layer to integrally form a metal-silicide layer that consumes part of the silicon layer but leaves at least some of the silicon layer between the first dielectric layer and the metal-silicide layer. In some instances, the metal layer may include one or more of platinum (Pt), gold (Au), palladium (Pd), molybdenum (Mo), titanium (Ti), tungsten (W), hafnium (Hf), zirconium (Zr), chromium (Cr), Cobalt (Co), Copper (Cu), Nickel (Ni), Vanadium (V), Iron (Fe), Manganese (Mn) and Tantalum (Ta). Additionally, the silicon layer may include one or more of polysilicon, amorphous silicon, crystalline silicon or silicon-germanium (SiGe). The resultant sensing element may have a near linear positive or negative temperature coefficient of resistance (TCR), if desired.

The preceding summary is provided to facilitate an understanding of some of the features of the present disclosure, and is not intended to be a full description. A full appreciation of the disclosure can be gained by taking the entire specification, claims, drawings, and abstract as a whole.

### BRIEF DESCRIPTION

The disclosure may be more completely understood in consideration of the following detailed description of various illustrative embodiments of the disclosure in connection with the accompanying drawings, in which:

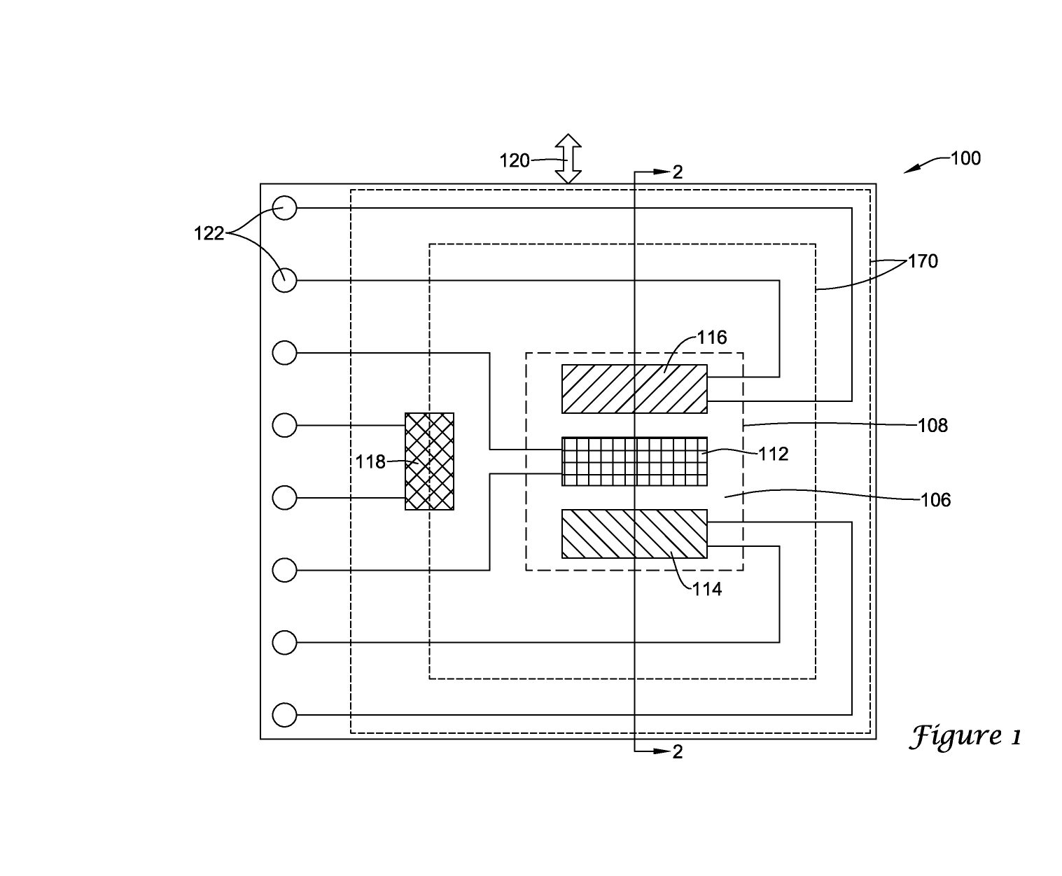

FIG. 1 is a schematic top view of an illustrative flow sensing die;

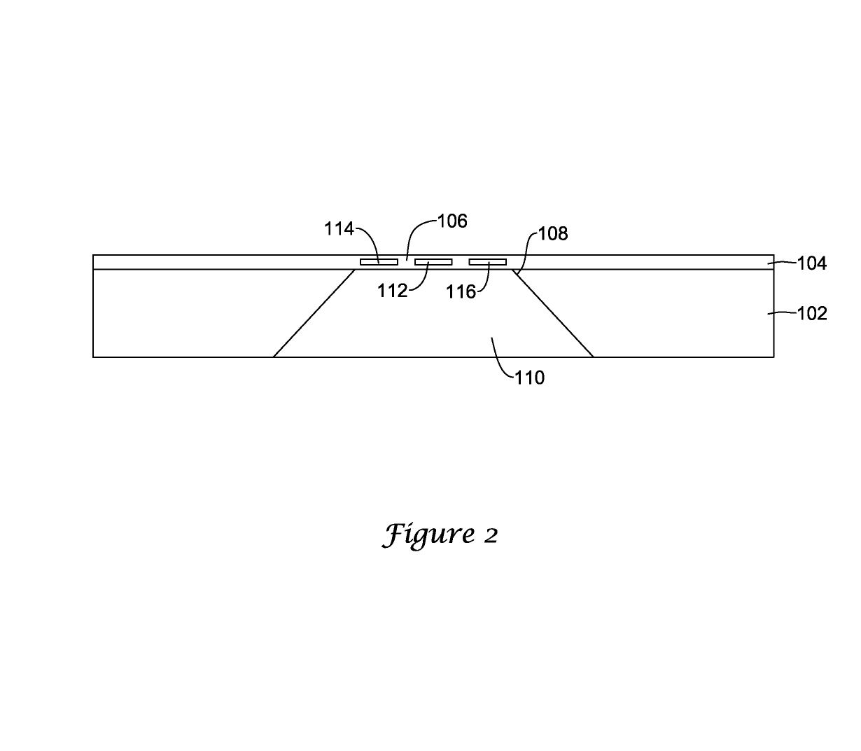

FIG. 2 is a schematic cross-sectional view of the illustrative flow sensing die of FIG. 1 taken along line 2-2;

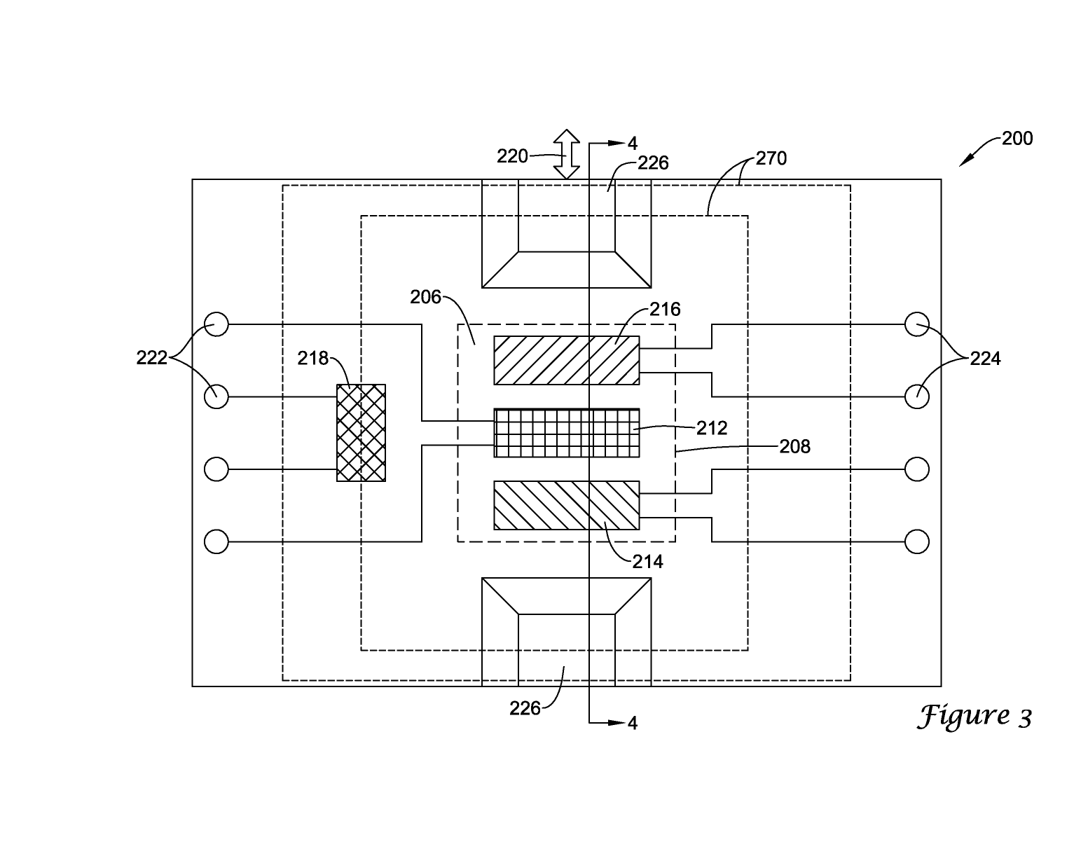

FIG. 3 is a schematic top view of another illustrative flow sensor die;

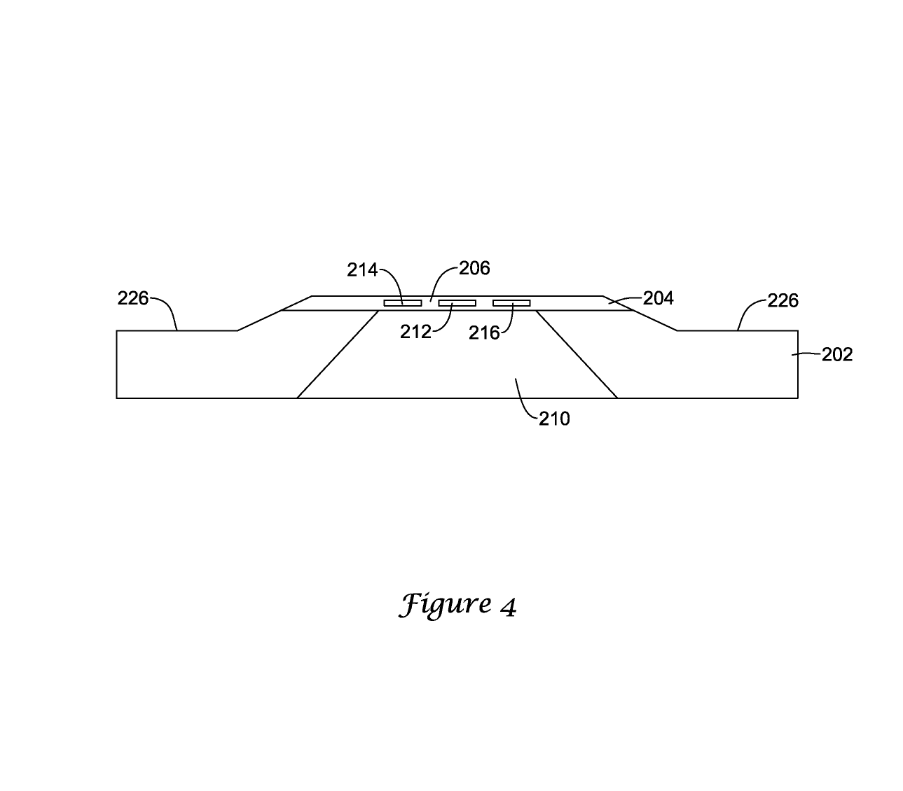

FIG. 4 is a schematic cross-sectional view of the illustrative flow sensor die of FIG. 3 taken along line 4-4;

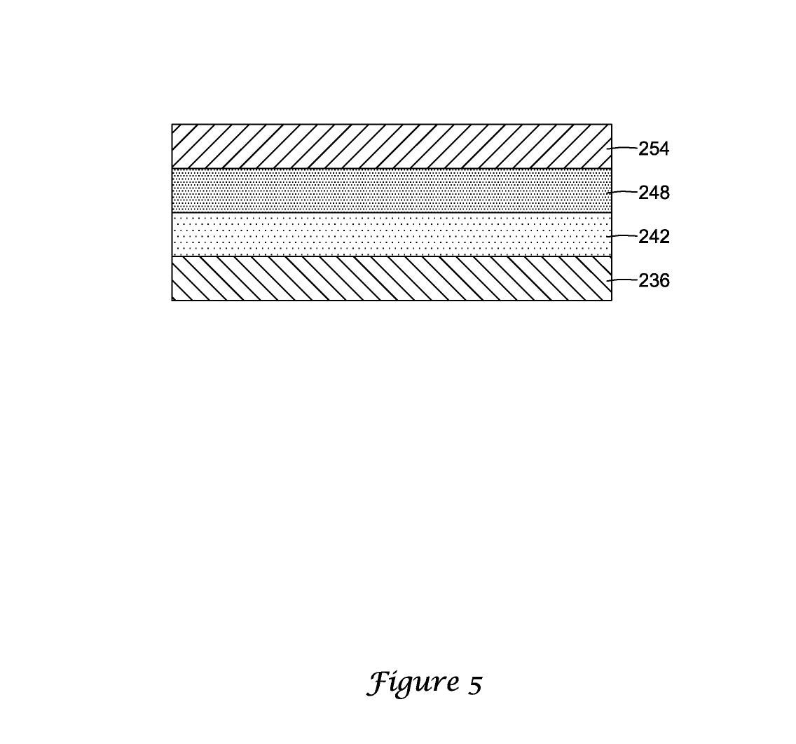

FIG. 5 is a schematic, cross-sectional view of an illustrative heating and/or sensing element;

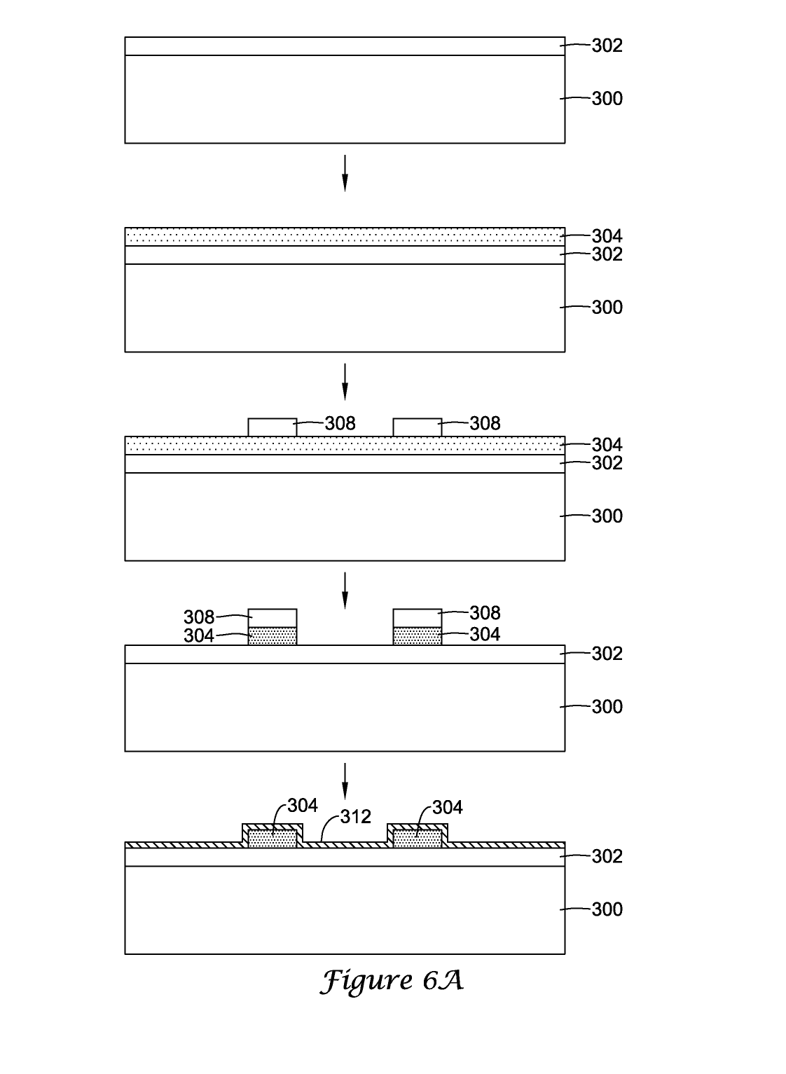

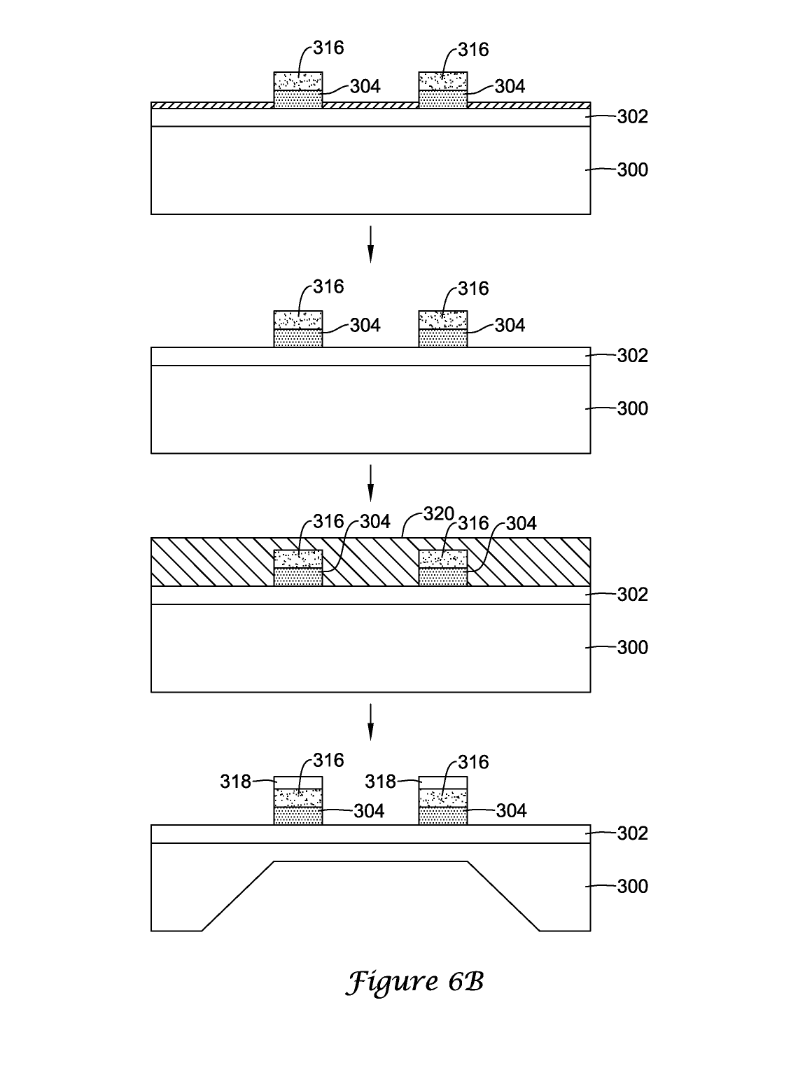

FIGS. 6A-6B show cross-sectional views of an illustrative method of fabricating an exemplary flow sensing die such as, for example, the flow sensing die shown in FIG. 1; and

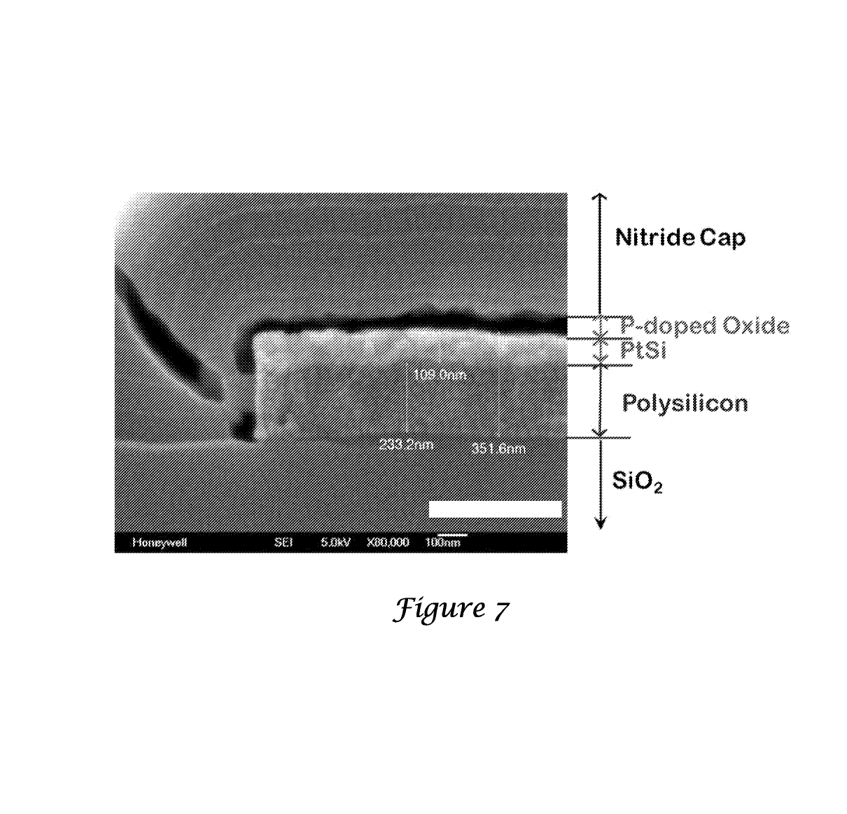

FIG. 7 is a scanning electron microscope (SEM) image showing a cross-sectional view of an exemplary sensing element fabricated according to an exemplary method as described herein.

### DESCRIPTION

The following description should be read with reference to the drawings wherein like reference numerals indicate like elements throughout the several views. The description and drawings show several embodiments which are meant to be illustrative of the present disclosure, and not limiting.

FIGS. 1 and 2 are schematic top and cross-sectional views of an illustrative flow sensing die 100 for measuring a fluid flow rate of a fluid passing in a flow direction through a fluid channel, which may be provided on a bottom side of the flow sensing die 100 through void 110 or on a top side of the flow sensing die 100, as desired. While a flow sensor is used as an example, it is contemplated that the disclosure can be applied to any suitable sensor that includes sensor elements such as resistors, heaters and/or other sensor elements. Such sensors may include, for example, flow sensors, thermal conductivity sensors, chemical sensors, pressure sensors, and/or other types of sensors, as desired. The term “fluid”, as used herein, can refer to a gas or a liquid, depending on the application. In the illustrative embodiment of FIG. 1, the flow sensing die 100 may be exposed to and/or disposed in a fluid channel to measure one or more properties of a fluid flow, such as mass flow and/or velocity of the fluid flow.

With reference to FIGS. 1-2, the illustrative flow sensing die 100 may include a substrate 102 having one or more thin film layers 104. Thin film layer or layers 104 may be formed from any suitable materials, using any suitable manufacturing technique(s), such as thin film deposition methods. Suitable thin film materials may include silicon, silicon oxide, silicon dioxide, silicon nitride, silicon oxynitride, and/or any other suitable material or material combination. In some cases, the thin film layer(s) 104 may form a membrane 106 or diaphragm that is considered part of or supported by substrate 102. As shown, a membrane border 108 may demark the area of thin film layers 104 that form the suspended membrane. The flow sensing die 100 may have a cavity 110 (see FIG. 2) formed in substrate 102. Void 110 may be formed in any suitable manner, such as, for example, by wet etching or deep reactive ion etching the back side of the substrate 102. In some cases, a bottom-most layer of the thin film layer(s) 104 may be an etch-stop layer to aid in wet etching of the substrate 102, but this is not required. For example, an etch-stop layer may be a separate layer such as an oxide, nitride or other layer that may help fabricate the membrane of a well-defined thickness. In some cases, the flow sensing die 100 may begin as a Silicon-On-Insulator (SOI) die, wherein the insulator layer may form the etch stop layer, and the silicon layer may form at least part of the suspended membrane (e.g. one of thin film layers 104).

In the illustrative embodiment of FIGS. 1-2, the one or more of the thin film layers 104 may also define one or more heater elements, such as heater element 112, and one or more sensing elements, such as sensing elements 114 and 116. As shown, a first sensing element 114 can be positioned upstream of the heater element 112 and a second sensing element 116 can be positioned downstream of the heater element 112 relative to the direction of fluid flow 120. However, this is not meant to be limiting, and it is contemplated that, in some embodiments, the fluid channel may be a bi-directional fluid channel such that the first sensing element 114 is positioned downstream of the heater element 112 and the second sensing element 116 is positioned upstream of the heater element 112. In some instances, only one sensing element may be provided, and in other embodiments, three or more sensing elements may be provided, depending on the application. In some cases, both sensing elements 114 and 116 may be positioned upstream (or downstream) of the heater element 112, if desired.

In some instances, the first sensing element 114 and the second sensing element 116 may be thermally sensitive resistors that have a near (or substantially) linear positive or negative temperature coefficient of resistance, such that the resistance varies linearly with temperature. In some cases, the first and second sensing elements 114 and 116 may be thermistors. In some instances, the first sensing element 114, the second sensing element 116, and any additional sensing elements, may be arranged in a Wheatstone bridge configuration, but this is not required.

In the illustrative embodiment of FIGS. 1-2, fluid may be directed to flow past flow sensing die 100 in a flow direction denoted by directional arrows 120. In the example shown, when no fluid flow is present, and the heater element 112 is heated to a temperature higher than the ambient temperature of the fluid in the fluid flow or, in other words, heater element 112 may dissipate electrical energy as heat, warming the fluid in its proximity. In this case, a temperature distribution may be created in the fluid, which is transmitted in a generally symmetrical distribution about the heater element 112 to upstream sensing element 114 and downstream sensing element 116. In this example, upstream sensing element 114 and downstream sensing element 116 may sense the same or similar temperature (e.g. within 25 percent, 10 percent, 5 percent, 1 percent, 0.001 percent, etc.). In some cases, this may produce the same or similar output voltage in the first sensing element 114 and the second sensing element 116.

When a fluid flow is present in the fluid channel, and the heater element 112 is activated and heated to a temperature higher than the ambient temperature of the fluid in the fluid flow, the symmetrical temperature distribution may be disturbed and the amount of disturbance may be related to the flow rate of the fluid flow in the fluid channel. In this example, the flow rate of the fluid flow may cause the upstream sensing element 114 to sense a relatively cooler temperature than the downstream sensing element 116. In other words, the flow rate of the fluid flow may cause a temperature differential between the upstream sensing element 114 and the downstream sensing element 116 that is related to the flow rate of the fluid flow in the fluid channel. In some cases, the temperature differential between the upstream sensing element 114 and the downstream sensing element 116 may result in an output voltage differential between the upstream sensing element 114 and the downstream sensing element 116.

In another illustrative embodiment, the mass flow and/or velocity of the fluid flow may be determined by providing a transient elevated temperature condition in the heater element 112, which in turn, may cause a transient elevated temperature condition (e.g., heat pulse) in the fluid flow. When there is a non-zero flow rate in the fluid flow, the upstream sensing element 114 may receive a transient response later than the downstream sensing element 116. The flow rate of the fluid flow can then be computed using the time lag between the upstream sensing element 114 and downstream sensing element 116, or between the time the heater element 112 is energized and when the corresponding elevated temperature condition (e.g., heat pulse) is sensed by one of the sensors, such as the downstream sensing element 116.

Performance of the flow sensing die 100 may be dependent on heat transferred to the sensing elements 114 and 116 through the fluid, and not through other heat conduction paths. In the illustrative embodiment shown, membrane 106 may substantially thermally isolate the heater element 112 and sensing elements 114 and 116 from the substrate 102. Without such thermal isolation, heat may be conducted to/from the flow sensor components from/to the substrate 102, which may reduce the sensitivity and/or performance of the sensing die 100. Material selection may provide an additional or alternative way to help thermally isolate the sensing elements 114 and 116, which may be used in flow sensors with or without thermally-isolating membranes. For example, low thermal conductivity materials may be used for the substrate 102, such as fused silica, fused quartz, and/or borosilicate glass. Additionally or alternatively, thermal isolation may be achieved on a substrate with low thermal conductivity thin films such as oxidized porous silicon, nitrides, aerogels, or any other suitable materials. These are just some examples.

In the illustrative embodiment of FIG. 1, the flow sensing die 100 may include one or more wire bond pads 122 situated adjacent or on substrate 102. In some instances, the wire bond pads can be situated along one side of the substrate, as shown in FIG. 1, but this is not required.

In some illustrative embodiments, wire bond pads 122 may be disposed along multiple die edges, or at other locations on the sensing die 100, as desired. Wire bond pads 122 may be configured for communicating signals relative to the one or more flow sensing die elements, such as heater element 112 and/or sensing elements 114 and 116, and/or temperature sensing element 118. Wire bond pads may include or be formed primarily of gold, aluminum, copper, and/or any other suitable conductor material or material combination, as desired. Traces may be provided to electrically connect the wire bond pads 122 to appropriate flow sensor components. Although not shown, flow sensing die 100 may be combined with a top cap to form a fluid channel for receiving a fluid flow therethrough, if desired.

Other flow sensing die configurations are contemplated. For example, the flow sensing die may be configured as a microbridge or a Microbrick™ sensor assembly, but this is not required. Some illustrative methods and sensor configurations that are considered suitable for measuring the mass flow and/or velocity are disclosed in, for example, U.S. Pat. Nos. 4,478,076; 4,478,077; 4,501,144; 4,581,928; 4,651,564; 4,683,159; 5,050,429; 6,169,965; 6,223,593; 6,234,016; 6,502,459; 7,278,309; 7,513,149; and 7,647,842. It is contemplated that flow sensing die 100 may include any of these flow sensor configurations and methods, as desired. It should be recognized, however, that flow sensor 100 may be any suitable flow sensor, as desired. Also, and as indicated above, while a flow sensor 100 is used as an example, it is contemplated that the disclosure may be applied to other types of sensors including, for example, thermal conductivity sensors, self-heating sensors, chemical sensors, pressure sensors, and/or other types of sensors, as desired.

FIGS. 3 and 4 show a schematic top view and schematic cross-sectional view, respectively, of another illustrative flow sensor die 200. The illustrative flow sensor die 200 shares a number of features with flow sensor die 100. Flow sensor die 200 may include a membrane 206, which may include one or more thin film layers 204 that are part of and/or supported by a substrate 202, with one or more flow sensor components disposed on the membrane, such as a heater element 212 and sensing elements 214 and 216. Flow sensing die 200 may differ from flow sensing die 100 in that wire bond pads are located on both the left 222 and right 224 sides of flow sensing die 200, and/or grooves 226 can be formed in the die 200 to define, at least in part, an inlet and an outlet of a flow channel that extends past at least the flow sensor components.

The heater elements 112, 212 and/or sensing elements 114, 116, 214, and 216 may each be configured to have a near linear (or substantially linear) temperature coefficient of resistance (TCR). The TCR value may be different for each of the heater elements 112, 212 and sensing elements 114, 116, 214 and 216. In some cases, the heating elements 112, 212 may have a near zero or negative TCR, and the sensing elements 114, 116, 214 and 216 may have a TCR value of at least about 1000 ppm/° C., at least about 2000 ppm/° C., in the range from about 2000 ppm/° C. to about 4000 ppm/° C., or any other suitable value, as desired.

In many cases, the heater elements 112, 212 and/or the sensing elements 114, 116, 214, and 216 may include at least one silicon layer and at least one metal-silicide layer. In some cases, the metal-silicide layer is integrally formed with the silicon layer. In some cases, the heater elements 112, 212 and/or the sensing elements 114, 116, 214, and 216 may each also include one or more dielectric layers. For example, in some cases, and as shown in the example of FIG. 5, the heater elements 112, 212 and/or the sensing elements 114, 116, 214, and 216 may include a first dielectric layer 236, a silicon layer 242 deposited on and in contact with the first dielectric layer 236, a metal-silicide layer 248, and a second dielectric layer 254 situated on and in contact with the metal-silicide layer 248. In some cases, the metal-silicide layer 248 is integrally formed with the silicon layer 242, and is separated from the first dielectric layer 236 by the silicon layer 242. In some instances, the silicon layer 242 may promote adhesion of the metal-silicide layer 248 to the first dielectric layer 236, and may help control the resistance and/or TCR of the resulting sensor element.

In some instances, the first dielectric layer 236 may be any suitable dielectric material. Suitable dielectric materials may include, but are not limited to, silicon oxide, silicon nitride, silicon oxynitride, and the like. The silicon layer 242 may include, but is not limited to, polysilicon, amorphous silicon, crystalline silicon, silicon-germanium (SiGe), and the like. In some cases, the first dielectric layer 236 and the silicon layer 242 correspond to the insulating layer and silicon layer, respectively, of a silicon-on-insulator (SOI) wafer, but this is not required. In some cases, the silicon layer 242 may be doped to modulate the resistivity of the silicon layer 242. Exemplary dopants may include, but are not limited to phosphorous (P), boron (B), arsenic (As), antimony (Sb), gallium, aluminum, and/or the like.

The metal-silicide layer 248 may be formed by first depositing a metal layer on the silicon layer 242, followed by sintering to produce a metal-silicide layer 248 in a process referred to as silicidation, as will be described in greater detail below. The metal layer, and thus the metal-silicide layer 248, may be formed using one or more metals including, but not limited to, platinum (Pt), gold (Au) palladium (Pd), molybdenum (Mo), titanium (Ti), tungsten (W), hafnium (Hf), zirconium (Zr), chromium (Cr), cobalt (Co), copper (Cu), nickel (Ni), vanadium (V), iron (Fe), manganese (Mn), and/or tantalum (Ta). These are just examples.

In some cases, the second dielectric layer 254 may be formed over the metal-silicide layer 248. The second dielectric layer 254 may be formed from any suitable dielectric material. Suitable dielectric materials may include, but are not limited to silicon oxide, silicon nitride, silicon oxynitride, and the like. In some cases, the second dielectric layer 254 may be deposited, grown, or otherwise formed over the metal-silicide layer 248. This may include using one or more deposition techniques such as sputtering, plasma vapor deposition, and chemical vapor deposition, to name a few. In some instances, the second dielectric layer 254 may be produced during the silicidation process, where some of the silicon atoms and/or dopant atoms in the silicon layer 242 diffuse through the metal-silicide layer 248 and becoming oxidized, thereby forming the second dielectric layer 254. Regardless of how formed, the second dielectric layer 254 may function as a low stress upper adhesion layer that supports further thin film deposition.

The TCR of each of the heater and/or sensing elements 112, 212, 114, 116, 214 and 216 may be controlled, at least in part, by controlling the thickness of the silicon layer 242 and/or the metal-silicide layer 248 that is used to form the heater or sensing elements 112, 212, 114, 116, 214, and 216. Additionally, the concentration of dopant in the silicon layer 242 may also be used, in part, to control the TCR of the heater and/or sensing elements 112, 212, 114, 116, 214, and 126. In some cases, the concentration of dopant in the silicon layer 242 may range from 10¹² cm⁻³ and 10²¹ cm⁻³. Other variables contributing to the TCR may include the initial silicon layer 242 thickness and the initial metal layer thickness (e.g. the thickness of the metal layer used to form the metal-silicide layer 248).

During the silicidation process used to form the metal-silicide layer 248, all the metal initially deposited onto the silicon layer 242 may be consumed to form the metal-silicide layer 248 and hence, the metal-silicide layer thickness tₘₛ will be determined, at least in part, by the initial metal thickness tₘ^{o},

tₘₛ=κₘtₘ. (1)

Additionally, to help ensure that at least part of the silicon layer 242 remains underneath the silicide film (e.g. to promote adhesion after silicidation), the initial silicon layer thickness may be

t_{Si}^{o}>κₘₛκₘtₘ^{o}+κₒₓtₒₓ. (2)

Where t^{o}_{Si} is the initial silicon layer thickness, tₘₛ and tₒₓ are the final metal-silicide and oxide layer thicknesses, respectively, κₘₛ is the thickness ratio of the metal silicide layer formed to the amount of silicon layer consumed, and κₒₓ is the thickness ratio of the oxide layer (e.g., second dielectric layer 254) to the amount of the silicon layer consumed. Thus, the remaining silicon layer thickness t_{Si} may be expressed as:

t_{Si}=t_{Si}^{o}−κₘₛtₘₛ−κₒₓtₒₓ. (3)

The sheet resistance of the composite film, including the metal-silicide layer 248 and the under lying silicon layer 242, may contribute to the overall TCR of the heater and/or sensing elements. For example, the sheet resistance can be derived based on the property of the two conductive films using equation (4), which is presented below:

$$SR = \frac{{ρ}_{m s} / {κ}_{m} {t}_{m}^{o}}{1 - ( {κ}_{m s} + \frac{{κ}_{ox} {t}_{ox}}{{κ}_{m} {t}_{m}^{o}} - \frac{{t}_{Si}^{o}}{{κ}_{m} {t}_{m}^{o}} ) \frac{{ρ}_{m s}}{{ρ}_{Si}}} \qquad ( 4 )$$

Where the ρₘₛ and ρ_{Si} are the resistivities of the metal-silicide layer 248 and the remaining silicon layer 242, respectively. From equation (4), the temperature coefficient of the resistance (TCR) of the heating and/or sensing element 112, 212, 114, 116, 214, and/or 216 may be derived using equation (5), which is presented below:

$$TCR ≡ \frac{1}{SR} \frac{\partial SR}{\partial T} = {TCR}_{m s} [ \frac{1 - ( {k}_{m s} + \frac{{k}_{ox} {t}_{ox}}{{k}_{m} {t}_{m}^{o}} - \frac{{t}_{Si}^{o}}{{k}_{m} {t}_{m}^{o}} ) \frac{{TCR}_{Si}}{{TCR}_{m s}} \frac{{ρ}_{m s}}{{ρ}_{Si}}}{1 - ( {k}_{m s} + \frac{{k}_{ox } {t}_{ox}}{{k}_{m} {t}_{m}^{o}} - \frac{{t}_{Si}^{o}}{{k}_{m} {t}_{m}^{o}} ) \frac{{ρ}_{m s}}{{ρ}_{Si}}} ] \qquad ( 5 )$$

Where TCRₘₛ TCR_{Si} are the temperature coefficients of resistance for the metal-silicide layer 248 and the remaining silicon layer 242, respectively.

In some instances, the thickness tₘₛ may range from about 500 angstroms to about 1 micron, and the remaining silicon layer 242 thickness t_{Si} may range from about 100 angstroms to about 1 micron, but these are just examples. The TCR of the heating and/or sensing elements may be at least 1000 ppm/° C., at least about 2000 ppm/° C., in the range from about 2000 ppm/° C. to about 4000 ppm/° C., or any other suitable value, as desired.

FIGS. 6A-6B are cross-sectional views showing an illustrative method of fabricating a flow sensing die including at least one sensing element such as, for example, the flow sensing die 100 shown in FIG. 1. In some embodiments, the flow sensing die 100 may be fabricated as one of a plurality of flow sensing die on a silicon (or other suitable material) wafer.

As shown in FIG. 6A, a silicon wafer or other suitable substrate may be provided with a first dielectric layer 302 disposed thereon. The first dielectric layer 302 may be formed by, for example, oxidizing the top of the substrate 300, but this is not required. Other methods of forming the dielectric layer may be used, including various deposition methods. Next a silicon layer 304 (e.g., undoped silicon epitaxial layer) may be deposited or otherwise provided on the dielectric layer 302 using any suitable fabrication technique. In some cases, this basic structure may be provided by simply securing a silicon-on-insulator (SOI) wafer.

In some instances, the silicon layer 304 may then be doped with a suitable dopant, such as phosphorous (P), arsenic (As), boron (B), antimony (Sb), and/or the like. In some cases, the concentration of dopant in the silicon layer 242 may range from 10¹² cm⁻³ and 10²¹ cm⁻³. Next, a masking layer 308 may be provided on select portions or regions of the silicon layer 304. This may be followed by etching the exposed regions of the silicon layer 304. Any number of suitable etching techniques may be used. The masking layer 308 may then be removed, and a metal layer 312 may be deposited onto the surface of the dielectric layer 302 and remaining silicon layer 304. The metal layer 312, and thus the resulting metal-silicide layer 316, may be formed using one or more metals including, but not limited to, platinum (Pt), gold (Au) palladium (Pd), molybdenum (Mo), titanium (Ti), tungsten (W), hafnium (Hf), zirconium (Zr), chromium (Cr), cobalt (Co), copper (Cu), nickel (Ni), vanadium (V), iron (Fe), manganese (Mn), and/or tantalum (Ta). These are just examples.

The assembly may then be sintered for an appropriate amount of time at a suitable temperature to convert the metal layer 312 and the underlying silicon layer 304 to an integral metal-silicide layer (e.g. through silicidation). As discussed previously, substantially all the metal layer 312 that is deposited onto the silicon layer 304 may be consumed to form the metal-silicide layer 316, as shown in FIG. 6B. An amount of the silicon layer 304 may remain, which may facilitate adhesion between the newly formed metal-silicide layer 316 and the underlying dielectric layer 302, and may help control and/or define the resistivity and/or TCR of the resulting sensor elements. The remaining metal layer 312 may then be removed using, for example, an etching process.

A second dielectric layer 318 may be formed from any suitable dielectric material. Suitable dielectric materials may include, but are not limited to silicon oxide, silicon nitride, silicon oxynitride, and the like. In some cases, the second dielectric layer 318 may be deposited, grown, or otherwise formed over the metal-silicide layer 316. This may include using one or more deposition techniques such as sputtering, plasma vapor deposition, and chemical vapor deposition, to name a few. In some instances, the second dielectric layer 318 may be produced during the silicidation process, where some of the silicon atoms and/or dopant atoms in the silicon layer 304 diffuse through the metal-silicide layer 316 and becoming oxidized, thereby forming the second dielectric layer 318. Regardless of how formed, the second dielectric layer 318 may function as a low stress upper adhesion layer that supports further thin film deposition.

In some cases, a nitride layer or cap 320 may be deposited over the remaining metal-silicide layer 316, the exposed first dielectric layer 302, and the second dielectric layer 318. The nitride layer or cap 320 may be deposited via sputtering or via chemical or plasma vapor deposition. Additionally, in some cases, the substrate 300 may be back-side etched to define a void (e.g. void 110 of FIG. 2) using any suitable etching technique such as, for example, wet etching with anisostropic etchants (e.g., KOH, TMAH, or EDP) or dry, deep reactive ion etching.

### EXAMPLE

### Example 1

A silicon wafer was initially cleaned by a megasonic cleaning process. Next, the silicon wafer was oxidized under the conditions set forth in Table 1 below.

TABLE 1
Initial Oxidation Conditions

| | | | | | |
|---|---|---|---|---|---|
| Time (min) | 11 | 40 | 125 | 5 | 90 |
| Temp (° C.) | 800 | 1100 | 1100 | 1100 | 800 |
| Gas | O₂TCA | O₂ | Wet O₂ | N₂ | N₂ |

The thickness of the silicon oxide layer was determined to be about 9700 Å.

Next, polysilicon was deposited onto the silicon oxide layer. The polysilicon was deposited at an initial thickness of 3000 Å at a temperature of 620° C. The actual thickness of the resulting polysilicon layer was measured at 3120 Å.

Deposition of the polysilicon layer was followed by the introduction of a dopant. In this example, POCl₃ was introduced into the gaseous environment resulting in phosphorous as the dopant. The conditions for introduction of the dopant are set forth below in Table 2.

TABLE 2
Phosphorous Doping Conditions

| | | | | |
|---|---|---|---|---|
| Time (min) | 25 | 10 | 5 | 95 |
| Temp (° C.) | 975 | 975 | 975 | 700 |
| Gas | N₂O₂ | N₂O₂ N₂ | N₂O₂ | N₂ |

The measured sheet resistance of the resulting polysilicon layer was 19.9±0.3 Ω/sq.

Next, the polysilicon layer was patterned using a photo masking technique followed by plasma etching. The wafer was then cleaned.

Platinum was then deposited onto the surface of the wafer including the polysilicon layer at an initial thickness of 500 Å. The sheet resistance of the polysilicon layer including the platinum metal layer was measured and found to be 4.05±0.3 Ω/sq.

Silicidation of the platinum and polysilicon layers to form a platinum-silicide layer was carried out by sintering the wafer at 450° C. in a nitrogen environment for about 16 minutes and then in an ambient air environment for about 10 minutes. The remaining platinum metal was stripped from the wafer using Aqua Regia.

A SEM image of a resultant sensor element is shown in FIG. 7. The sensor element shown in FIG. 7 include a phosphorous doped oxide layer formed on the platinum silicide (via silicon atoms and dopant atoms diffusing through the platinum silicide and becoming oxidized), and a nitride cap.

The resultant thickness of the platinum-silicide layer was determined to be approximately 109.0 nm, which agreed with the theoretical prediction for the thickness of this layer. The thickness of the remaining polysilicon layer was determined to about 233.3 nm. The TCR of the sensor element was measured and found to be 2000 ppm/° C.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

What is claimed is:

1. A sensor element comprising:
a first dielectric layer;
a silicon layer on the first dielectric layer, the silicon layer doped with a concentration of a dopant; and
a metal-silicide layer integrally formed with the silicon layer, the metal-silicide layer separated from the first dielectric layer by the silicon layer.

2. The sensor element of claim 1, further comprising:
a second dielectric layer situated on the metal-silicide layer, the second dielectric layer including the dopant.

3. The sensor element of claim 1, wherein the first dielectric layer includes one or more of silicon oxide, silicon nitride or silicon oxynitride.

4. The sensor element of claim 1, wherein the silicon layer includes one or more of polysilicon, amorphous silicon, crystalline silicon and silicon-germanium (SiGe).

5. The sensor element of claim 1, wherein the silicon layer and the first dielectric layer correspond to a silicon film and an insulating film, respectively, of a silicon-on-insulator wafer.

6. The sensor element of claim 1, wherein the metal-silicide layer includes one or more of platinum (Pt), gold (Au), palladium (Pd), molybdenum (Mo), titanium (Ti), tungsten (W), hafnium (Hf), zirconium (Zr), chromium (Cr), Cobalt (Co), Copper (Cu), Nickel (Ni), Vanadium (V), Iron (Fe), Manganese (Mn) and Tantalum (Ta).

7. The sensor element of claim 1, wherein the dopant includes one or more of phosphorous (P), boron (B), Arsenic (As) and Antimony (Sb).

8. The sensor element of claim 1, wherein the concentration of the dopant in the silicon layer is between 10¹² cm⁻³ and 10²¹ cm⁻³.

9. The sensor element of claim 1, wherein the silicon layer has a thickness that is between 100 angstroms and 1 micron.

10. The sensor element of claim 1, wherein the metal-silicide layer has a thickness that is between 500 angstroms and 1 micron.

11. A flow sensor comprising:
a heater element;
an upstream sensing element situated upstream of the heater element;
a downstream sensing element situated downstream of the heater element;
wherein at least one of the heater element, the upstream sensing element and the downstream sensing element includes:
a first dielectric layer;
a silicon layer on the first dielectric layer, the silicon layer doped with a concentration of a dopant;
a metal-silicide layer integrally formed with the silicon layer, the metal-silicide layer separated from the first dielectric layer by the silicon layer; and
a second dielectric layer situated on the metal-silicide layer.

12. The flow sensor of claim 11, wherein the second dielectric layer includes the dopant.

13. The flow sensor of claim 11, wherein each of the heater element, the upstream sensing element and the downstream sensing element includes:
a first dielectric layer;
a silicon layer on the first dielectric layer, the silicon layer doped with a concentration of a dopant;
a metal-silicide layer integrally formed with the silicon layer, the metal-silicide layer separated from the first dielectric layer by the silicon layer; and
a second dielectric layer situated on the metal-silicide layer.

14. The flow sensor of claim 11, wherein the upstream sensing element and the downstream sensing element are included in a Wheatstone bridge.

15. The flow sensor of claim 11, wherein the heater element, the upstream sensing element and the downstream sensing element are all situated on a diaphragm that is supported by a substrate, wherein at least part of the substrate is etched away adjacent the diaphragm.

16. A method for making a sensor element, comprising:
providing a first dielectric layer;
providing a silicon layer on the first dielectric layer;
doping the silicon layer with a concentration of a dopant;
providing a metal layer on the silicon layer; and
heating the silicon layer and the metal layer to integrally form a metal-silicide layer that consumes part of the silicon layer but leaves at least some of the silicon layer between the first dielectric layer and the metal-silicide layer.

17. The method of claim 16, wherein the heating step causes a second dielectric layer to form on the metal-silicide layer opposite the silicon layer, wherein the second dielectric layer also includes the dopant.

18. The method of claim 16, wherein the metal layer includes one or more of platinum (Pt), gold (Au), palladium (Pd), molybdenum (Mo), titanium (Ti), tungsten (W), hafnium (Hf), zirconium (Zr), chromium (Cr), Cobalt (Co), Copper (Cu), Nickel (Ni), Vanadium (V), Iron (Fe), Manganese (Mn) and Tantalum (Ta).

19. The method of claim 16, wherein the metal layer is Pt, and the heating step including heating the silicon layer and the Pt layer to a temperature of at least 400° C. for at least 10 minutes.

20. The method of claim 16, wherein the silicon layer includes one or more of polysilicon, amorphous silicon, crystalline silicon or silicon-germanium (SiGe).
